(19) United States
(12) Patent Application Publication
(10) Pub. No.: US 2009/0000539 A1
(43) Pub. Date: Jan. 1, 2009

(54) APPARATUS FOR GROWING A NANOWIRE AND METHOD FOR CONTROLLING POSITION OF CATALYST MATERIAL

(76) Inventor: Theodore I. Kamins, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/771,082

(22) Filed: Jun. 29, 2007

(51) Int. Cl. C30B 19/00

(52) U.S. Cl. 117/54; 117/206; 977/763

(57) ABSTRACT

An apparatus for growing a nanowire includes a crystalline surface, and a feature formed on at least a portion of the crystalline surface. The feature has a region with high surface curvature. A catalyst material is established on the region.

### BACKGROUND

The present disclosure relates generally to an apparatus for growing a nanowire, and to a method for controlling the position of catalyst material.

Since the inception of semiconductor technology, a consistent trend has been toward the development of smaller device dimensions and higher device densities. As a result, nanotechnology has seen explosive growth and generated considerable interest. Nanotechnology is centered on the fabrication and application of nano-scale structures, or structures having dimensions that are often 5 to 100 times smaller than conventional semiconductor structures. Nanowires are included in the category of nano-scale structures.

Nanowires are wire-like structures having at least one linear dimension (e.g., diameter) ranging from about 3 nm to about 200 nm. Nanowires are suitable for use in a variety of applications, including functioning as conventional wires for interconnection applications or as semiconductor devices. Nanowires are the building blocks of many potential nano-scale devices, such as nano-scale field effect transistors (FETs), p-n diodes, light emitting diodes (LEDs) and nanowire-based sensors, to name a few.

Nanowires may be grown from catalyst materials. The positioning of such materials on some surfaces (e.g., vertical surfaces) is generally not controlled. This lack of control may make it difficult to position the catalyst materials at a desirable distance from a lower region of the vertical surface. In some instances, the lower bound of the catalyst material position may be controlled; however, such limited control often results in the random positioning of catalyst material in a top region of the vertical surface. Furthermore, catalyst materials often form on undesired regions of the substrate where such nanoparticles lead to unwanted nanowire growth, requiring complicated subsequent processing to remove them and obtain the desired structure.

### BRIEF DESCRIPTION OF THE DRAWINGS

Features and advantages of embodiments of the present disclosure will become apparent by reference to the following detailed description and drawings, in which like reference numerals correspond to similar, though not necessarily identical, components. For the sake of brevity, reference numerals or features having a previously described function may not necessarily be described in connection with other drawings in which they appear.

FIG. 1 is a flow diagram depicting an embodiment of the method for controlling positioning of a catalyst material;

FIGS. 2A through 2E depict schematic perspective views of an embodiment of the method for controlling positioning of a catalyst material;

FIGS. 3A through 3F depict schematic cross-sectional views of another embodiment of the method for controlling positioning of a catalyst material;

FIGS. 3A through 3D and 3G depict schematic cross-sectional views of still another embodiment of the method for controlling positioning of a catalyst material;

FIG. 4 is a schematic perspective view of an embodiment of an apparatus having a feature with one-dimensional termination; and

FIG. 5 is a schematic perspective view of an embodiment of an apparatus having a feature with zero-dimensional termination.

### DETAILED DESCRIPTION

Embodiments of the method disclosed herein advantageously enable control over the positioning of catalyst material, and the nanowire(s) grown therefrom, on a crystalline surface, for example, a vertical sidewall. Such control enables the catalyst material to be positioned a desirable distance from an edge (e.g., a lower region of a vertical surface) of the crystalline surface. Furthermore, the control enables the catalyst material to be positioned a desirable distance from the initial crystalline surface itself. As such, embodiments of the apparatus disclosed herein have catalyst material positioned at desirable x, y and z coordinates with respect to a crystalline surface.

Referring now to FIG. 1, one embodiment of the method for controlling catalyst material positioning is depicted. The method includes providing a crystalline surface, as shown at reference numeral 11; and growing a feature on at least a portion of the crystalline surface such that the feature has a region with high surface curvature, as shown at reference numeral 13. It is to be understood that this and other embodiments of the method and apparatus are described in further detail in reference to the other figures hereinbelow.

As used herein, the phrase “region with high surface curvature” generally refers to a portion of the feature that has at least one dimension that is equal to or less than a diameter of a catalyst nanoparticle that is to be established on the portion. In an embodiment, the region with high surface curvature is located at the angle where at least two facets join. As non-limiting examples, the region with the high surface curvature may be located at a zero-dimensional termination (e.g., a point), or at a one-dimensional termination (e.g., a line).

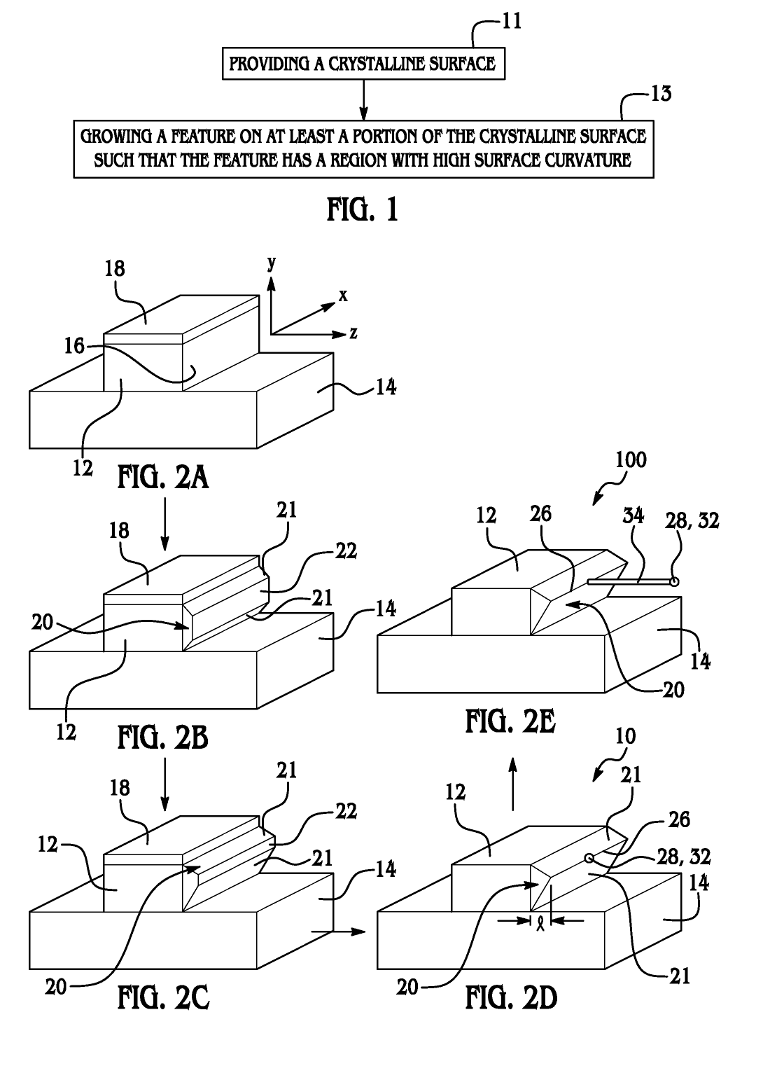

Referring now to FIGS. 2A through 2E, one embodiment of the method for controlling catalyst material positioning is depicted. It is to be understood that the method results in the formation of an embodiment of the apparatus 10 (shown in FIG. 2D) for growing a nanowire (reference numeral 34 in FIG. 2E). Once the nanowire 34 is grown, the resulting device 100 (an embodiment of which is shown in FIG. 2E) may be used in a variety of applications, including, but not limited to those applications utilizing field effect transistors (FETs), p-n diodes, light emitting diodes (LEDs), nanowire-based sensors, other electronic, mechanical and/or optical devices, or combinations thereof.

FIG. 2A depicts a structure 12 established on a substrate 14. It is to be understood that any suitable substrate 14 may be used. Non-limiting examples of suitable substrates include Si, Ge, silicon-on-insulator (on a Si wafer) (SOI), germanium-on-insulator (on a Si wafer) (GOI), silicon-on-sapphire (SOS), silicon-on-ceramic (SOC), and/or the like, and/or combinations thereof.

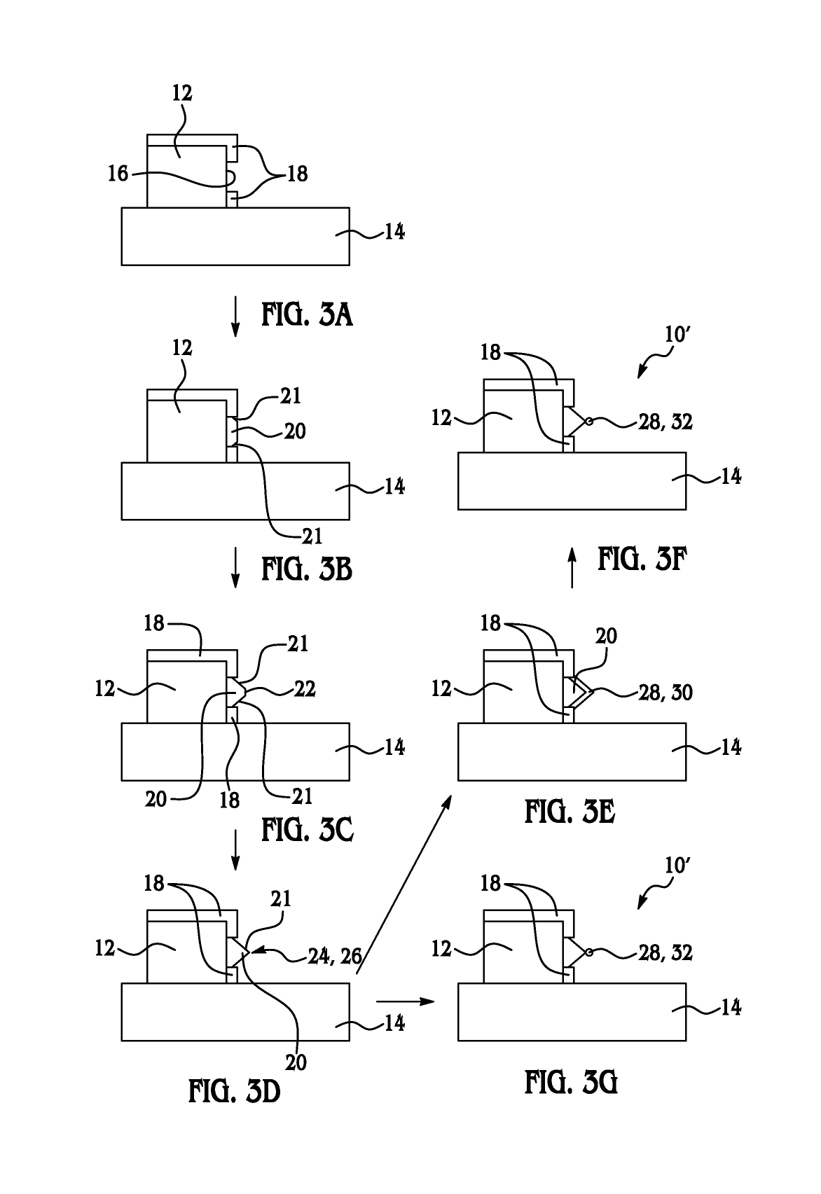

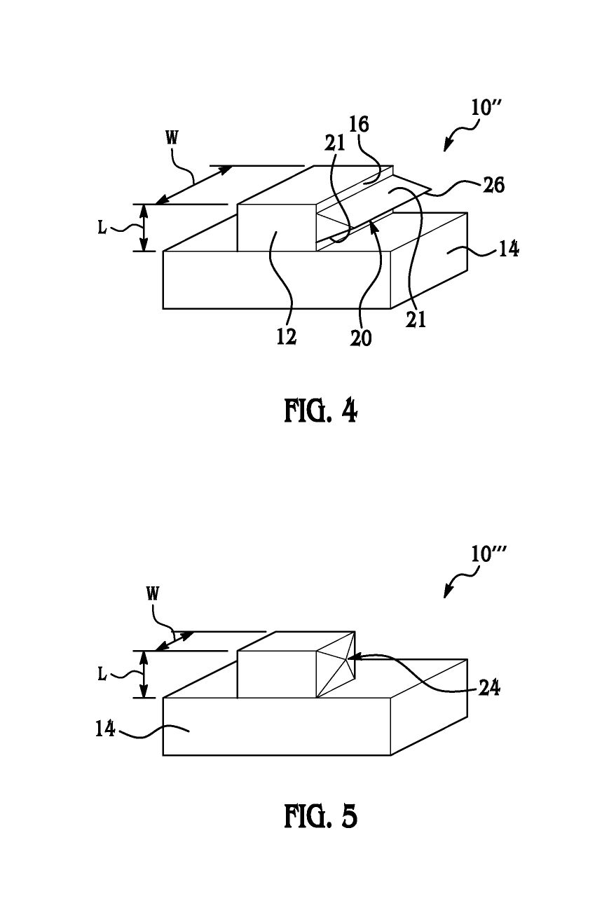

The structure 12 may be an electrode, a cavity sidewall, or any other object having at least one crystalline surface 16 upon which it is desirable to form one or more nanowire(s) 34 (see FIG. 2E). The crystalline surface 16 may be formed via any suitable technique, including lithography and etching. In one embodiment, the crystalline surface 16 is substantially vertical. In another embodiment, the crystalline surface 16 has any non-zero and non-ninety degree angle with respect to a surface plane of the substrate 14. In still another embodiment, the crystalline surface 16 is a substantially horizontal surface of limited extent (e.g., the surface 16 is surrounded by an oxide). While one structure 12 is shown in FIG. 2A, it is to be understood that any desirable number of structures 12 may be formed on the substrate 14. Furthermore, the structure 12 may be utilized without the substrate 14. The number of structures 12 formed or used depends, at least in part, on the desirable application for the apparatus 10, 10′ (see FIGS. 3F and 3G), 10″ (see FIG. 4), 10′″ (see FIG. 5).

The crystalline surface 16 may be formed of any crystalline material, including, but not limited to Si, Ge, GaAs, InP, sapphire (i.e., single crystal Al₂O₃), or the like, or combinations thereof. The crystalline material may be conducting (e.g., for use in electrical applications) or non-conducting (e.g., for use in non-electrical applications), depending, at least in part, on the desirable application of the apparatus 10, 10′, 10″, 10′″ or device 100. It is believed that the crystalline surface 16 contributes to epitaxially growing controlled facets 21.

The feature 20 (see FIGS. 2B-2E) may be formed on substantially the entire crystalline surface 16 of the structure 12. Further, a mask layer 18 may be established on one or more of the other surfaces of the structure 12 to aid in the selective growth of the feature 20 on the crystalline surface 16. Any material capable of withstanding growth processing temperatures may be selected for the mask layer 18, non-limiting examples of which include oxides, nitrides, or the like, or combinations thereof. Processes suitable for establishing the mask layer 18 include, but are not limited to thermal oxidation, low-pressure chemical vapor deposition (LPCVD), plasma enhanced chemical vapor deposition (PECVD), atmospheric pressure chemical vapor deposition (APCVD), or any other suitable chemical or physical vapor deposition or growth technique.

Referring now to FIG. 2B, the feature 20 is grown from the crystalline surface 16. In an embodiment, epitaxy or selective epitaxy is used to grow the feature 20 from the crystalline surface 16. Epitaxial or selective epitaxial growth may be accomplished via chemical vapor deposition epitaxy or molecular beam epitaxy. Embodiments employing selective epitaxial growth generally involve depositing or growing the feature 16 on at least a portion of the crystalline surface 16, but not on other materials.

It is to be understood that growth of the feature 20 relies, at least in part, on the fact that different crystallographic planes have different growth rates (discussed further hereinbelow). As such, the crystalline surface 16 may affect the growth of the feature 20.

In an embodiment, as the feature 20 grows, facets 21 are formed, and a portion of the feature 20 remains substantially parallel to the crystalline surface 16. FIG. 2B illustrates two facets 21 and the parallel portion 22 of the feature 20. In another embodiment, as the feature 20 grows, the facets 21 are formed, and the growth front of the feature 20 is not substantially parallel to the crystalline surface 16. As a non-limiting example, the crystalline surface 16 may not be, but is close to, a low-index plane. In this example embodiment, the growing front plane of the feature 20 may then become the low-index plane, although not directly parallel to the surface 16. As another non-limiting example, the crystalline surface 16 is not smooth or regular, and the front plane of the growing feature 20 becomes smoother and more regular as it grows.

FIG. 2C depicts the feature 20 as growth continues. The growth area of the parallel portion 22 of the growing feature 20 may become limited by slowly growing crystal planes or facets 21, which form and bound the feature 20. These facets/crystal planes 21 are inclined with respect to the crystalline surface 16. In an embodiment, the slowest growing facets 21 bound the feature 20 during growth. It is to be understood that the inclined crystal planes 21 may be equivalent by symmetry or non-equivalent by symmetry. It is to be further understood that, generally, the growth of the facets 21 depends upon, at least in part, the materials and growth conditions used. As previously indicated, the ratio of the growth rate of various crystal planes/facets 21 may be controlled by adjusting the gas-phase and/or surface chemistry of the epitaxy process. As a non-limiting example, for silicon, relative growth rates may be controlled by gas-phase chemistry (e.g., Cl:Si ratio of the gaseous precursors). As another non-limiting example, the relative growth rates of (110) and (100) crystal planes 21 may be varied by adjusting the ratio of SiH₄ to HCl in the growth ambient. This technique is further described in “Control of lateral epitaxial chemical vapor deposition of silicon over insulators”, by Bradbury et al., published in J. Appl. Phys. Vol. 55, 519-523 (15 Jan. 1984), which is incorporated herein by reference.

It is to be understood that the inclined facets or planes 21 of the feature 20 continue to grow, but at lower rates than the growth rate of the parallel portion 22 of the feature 20. It is believed that, during continued crystal growth, the more rapid growth of the parallel portion 22 and the slower growth of the inclined crystal planes 21 causes the parallel portion 22 of the feature 20 to decrease in area, and the surface area of the parallel portion 22 to approach zero. As the surface area of the parallel portion 22 approaches zero, a zero-dimensional termination (e.g., a point, shown as reference numeral 24 in FIG. 5) or a one-dimensional termination (e.g., a line, shown as reference numeral 26 shown in FIGS. 2D, 2E and 4) is formed.

Generally, a zero-dimensional point 24 (FIG. 5) is formed when the crystalline surface 16 has an equal length L and width W (shown in FIG. 5); and a one-dimensional termination 26 is formed when the crystalline surface 16 has a different length L and width W (shown in FIG. 4).

FIG. 2D illustrates the feature 20 after the one-dimensional termination 26 has been formed. In this embodiment, the one-dimensional termination 26 is the region of the feature 20 having high surface curvature, and is located at the angle where two facets 21 of the feature 20 join together.

It is to be understood that once the one-dimensional termination 26 (or zero-dimensional termination 24 in other embodiments) is formed, subsequent growth of the facets 21 of the feature 20 retains the one-dimensional termination 26 (or zero-dimensional termination 24) for at least a portion of the growth period. It is to be understood that generally the shape of the termination 24, 26 is retained, however, the position of the termination 24, 26 may shift. In an embodiment in which the inclined facets 21 have substantially the same growth rate, the termination 24, 26 is maintained throughout growth. In an embodiment in which the inclined facets 21 have different growth rates, a larger portion of the feature 20 formed by the two facets 21 will be bounded by the slower growing facet 21 as the feature 20 continues to grow. When the faster growing facet 21 is overtaken by the slower growing facet 21, the faster growing facet 21 may cease to exist, the previously existing termination 24, 26 may change, and another termination 24, 26 may be formed between other facets 21.

Growth may be stopped prior to formation of the termination 24, 26, however, it is to be understood that growth of the feature 20 is continued at least until the region at which the inclined facets 21 join the parallel portion 22 has a desirable surface curvature for receiving catalyst material 28. In an embodiment, this region has a higher surface curvature than a curvature of the crystalline surface 16. In a non-limiting example, a maximum (e.g., approaching infinite) surface curvature is desirable.

Furthermore, growth may be continued such that the termination 24, 26 of the feature 20 has a desirable distance from the crystalline surface 16. As previously stated, the shape of the termination 24, 26 is retained as growth continues. As such, the feature 20 may be grown to a desirable length l (shown in FIG. 2D), with such length l potentially being limited by the growth rates of the facets 21 (e.g., facets 21 having different growth rates, as previously described). This enables substantial control over the position of the catalyst material 28 in the z coordinate with respect to the crystalline surface 16. In a non-limiting example, a longer length l may be desirable in order to control resistance between two electrodes when physical spacing between surfaces 16 is fixed or limited by other constraints.

FIG. 2D also depicts the catalyst material 28 established on the one-dimensional termination 26 of the feature 20. It is to be understood that the catalyst material 28 may be a layer (shown as reference numeral 30 in FIG. 3E) that is selectively or non-selectively established and subsequently annealed to form nanoparticles, or may be pre-formed catalyst nanoparticles 32 (also shown in FIGS. 3F and 3G). In either embodiment, selective deposition processes include selective chemical vapor deposition, selective electrochemical deposition, or selective attraction of pre-formed catalyst nanoparticles. Some non-selective deposition processes include physical vapor deposition processes (e.g., electron-beam evaporation or sputtering).

“Selective deposition,” as used herein, means that the combination of the catalyst material 28 and the material(s) on which it is to be deposited (and/or not deposited) are selected such that the catalyst material 28 preferentially deposits on one material instead of on another material, and/or that the deposition technique is selected such that the catalyst material 28 is established at the termination 24, 26 instead of on the facets 21 of the growing feature 20. The catalyst material 28 may be selected such that it deposits preferentially on exposed Si and not on SiO₂. As non-limiting examples, Ti will preferentially deposit on Si but will not deposit on SiO₂ when using chemical vapor deposition from TiCl₄, while Ti will deposit on Si and on SiO₂ when using electron-beam evaporation. As another non-limiting example, Au will preferentially deposit on Si when using electrochemical deposition. Furthermore, when the catalyst nanoparticle 28, 32 is established via electrochemical deposition on a feature 20 composed of a single material, the field concentration at the termination 24, 26 aids the positioning of the catalyst nanoparticle 28, 32 at the termination 24, 26. A non-limiting example of selective deposition is discussed in Yasseri et al., “Electroless Deposition of Au Nanocrystals on SiO₂ Surfaces as Catalysts for Epitaxial Growth of Si Nanowires,” Electrochem. and Solid-State Lett., Vol. 9, pp. C185-188 (December 2006).

The catalyst material 28 may be any material suitable for initiating growth of nanowires 34. Non-limiting examples of such materials include gold, titanium, platinum, palladium, gallium, aluminum, nickel, and/or combinations thereof.

Still further, FIG. 2D depicts the removal of the mask layer 18. Such removal may be accomplished by etching. In an embodiment, the etching technique is selected from chemically selective wet or dry etching.

In some embodiments, it may be desirable to retain the mask layer 18 during nanowire 34 growth and/or in the finished apparatus 10, 10′, 10″, 10′″. For example, leaving the mask layer 18 during nanowire 34 growth may aid in substantially preventing the catalyst material 28 or the nanowire material from depositing on the top or other sides of the structure 12 (e.g., post or electrode). If desirable, one or more regions of the mask layer 18 may be removed later (e.g., after nanowire 34 growth), for example, to allow electrical contact to be made.

Referring now to FIG. 2E, an embodiment of the device 100 with a nanowire 34 grown from the feature 20 is depicted. In an embodiment, the growth of the nanowire 34 is accomplished by exposing the catalyst material 28 to a precursor gas that initiates and continues growth of the nanowire 34. It is to be understood, however, that any suitable method for growing nanowires 34 may be employed. Non-limiting examples of such methods are vapor-liquid-solid (VLS) and vapor-solid-solid (VSS). For either of these techniques, chemical vapor deposition is particularly suitable for supplying Si atoms. VLS is further described in Sharma et al, “Synthesis of Thin Silicon Nanowires using Gold Catalyzed Chemical Vapor Deposition,” Appl. Phys. A, 80, 1225-1229 (March 2005), and Sharma et al, “Diameter Control of Ti-catalyzed Silicon Nanowires,” J. Crystal Growth, 267, 613-618 (2004), both of which are incorporated by reference herein in their entirety. VSS is further described in Kamins et al., “Ti-Catalyzed Si Nanowires by Chemical Vapor Deposition: Microscopy and Growth Mechanisms,” J. Appl. Phys., 89, 1008-1015 (January 2001), incorporated by reference in its entirety.

Referring now to FIGS. 3A through 3F, another embodiment of the method for forming the apparatus 10′ is depicted. As shown in FIG. 3A, in this embodiment of the method, the mask layer 18 is established on one or more portions of the crystalline surface 16, such that at least another portion of the crystalline surface 16 remains exposed. Any of the previously described materials and establishing techniques suitable for the mask layer 18 may be used in this embodiment.

The mask layer 18 may be positioned in any desirable configuration, as long as some of the crystalline surface 16 remains exposed. Generally, the mask layer 18 is formed at desirable x and y coordinates on the crystalline surface 16 such that the remaining exposed portion of the surface 16 is located at a desirable position for forming the feature 20. In an embodiment, the mask layer 18 may be established such that the exposed portion of the surface 16 is located at a desirable distance from all edges of the structure 12. It is to be understood that the establishment of the mask layer 18 may also depend, at least in part, on the desirable position for the nanowire 34.

FIG. 3B depicts the growth of the feature 20 from the exposed crystalline surface 16. As depicted, the mask layer 18 prevents the lateral spread of the initial portions of the growing feature 20. Facets 21 initiate adjacent to the mask layer 18 and limit the area (i.e., parallel portion 22) of the feature 20 growing parallel to the crystalline surface 16. As feature 20 growth progresses, the parallel portion 22 of the feature 20 decreases. Furthermore, it is to be understood that growth may be expanded laterally after growth perpendicular to the surface 16 exceeds the mask layer 18 thickness. As such, the mask layer 18 in this embodiment of the method enables one to control the position of the feature 20 on the crystalline surface 16.

FIGS. 3C and 3D depict further growth of the facets 21 and formation of the termination 24, 26, as described in further detail hereinabove. It is to be understood that this embodiment of the method may be used to form either the zero-dimensional termination 24 or the one-dimensional termination 26.

As previously mentioned, FIG. 3E depicts the catalyst material 28 established as a layer 30. In this embodiment, the catalyst material 28 may be selectively or non-selectively deposited on the feature 20, as previously described. The layer 30 is then annealed to form nanoparticles 32, which preferentially position themselves at the termination 24, 26 (see FIG. 3F).

FIGS. 3A through 3D and 3G together depict sill another embodiment of the method for forming the apparatus 10′. After the feature 20 is formed (see FIG. 3D), the catalyst material 28 (in the form of a catalyst nanoparticle 32) is selectively established at the termination 24, 26, using deposition techniques previously described.

In the embodiments shown in the FIG. 3 series, the mask layer 18 may be removed as previously described.

Referring now to FIGS. 4 and 5 together, two respective embodiments of the apparatus 10″, 10′″ are depicted prior to establishment of the catalyst material 28 and growth of the nanowire 34. In FIG. 4, a one-dimensional termination 26 is formed, and the feature 20 is not formed on the entire crystalline surface 16. To obtain the one-dimensional termination 26, the crystalline surface 16 has non-equal length L and width W, or a crystallographic structure that promotes non-symmetric growth of the facets 21. Furthermore, in forming this embodiment, the mask layer 18 (not shown) would be used to cover those portions of the crystalline surface 16 in which it is desirable to prevent formation of the feature 20. As shown in FIG. 4, the mask layer 18 would have been positioned near the upper and lower edges of the crystalline surface.

As shown in FIG. 5, a zero-dimensional termination 24 is formed, and the feature 20 is formed on the entire crystalline surface 16. In one embodiment, to obtain the zero-dimensional termination 24, the crystalline surface 16 has equal length L and width W. In other embodiments, where the facets 21 grow asymmetrically, the zero-dimensional termination 24 is obtained by a proper compensating choice of length L and width W, based on the known growth rates of the relevant crystal planes, thereby causing all growing facets 21 to converge at a point.

In the embodiment shown in FIG. 5, the mask layer 18 is not used, and growth results from the entire crystalline surface 16. In other embodiments that form a zero-dimensional termination 24, a mask layer 18 with an opening having a proper length L and width W may be used to limit the area of the growing feature 20. Generally, in these embodiments, when the facets 21 grow symmetrically, L and W are equal, and when the facets 21 grow asymmetrically, L and W are selected so that the growing facets 21 converge at a point.

Embodiments of the method, apparatus 10, 10′, 10″, 10′″ and device 100 disclosed herein include, but are not limited to the following advantages. The method(s) enable the catalyst material 28 to be positioned at any desirable x, y, and z coordinates with respect to the crystalline surface 16. As such, the distance between the catalyst material 28 (and/or the nanowire 34) and the respective edges of the crystalline surface 16 is controllable.

While several embodiments have been described in detail, it will be apparent to those skilled in the art that the disclosed embodiments may be modified. Therefore, the foregoing description is to be considered exemplary rather than limiting.

What is claimed is:

1. An apparatus for growing a nanowire, the apparatus comprising:
a crystalline surface;
a feature formed on at least a portion of the crystalline surface, the feature having a region with high surface curvature; and
a catalyst material established on the region.

2. The apparatus as defined in claim 1 wherein the feature is epitaxially grown.

3. The apparatus as defined in claim 1 wherein the crystalline surface is formed of Si, Ge, GaAs, InP, sapphire, or combinations thereof.

4. The apparatus as defined in claim 1 wherein the catalyst material is selected from gold, titanium, platinum, palladium, nickel, gallium, aluminum and combinations thereof.

5. The apparatus as defined in claim 1 wherein the region with high surface curvature has at least one dimension that is equal to or less than a diameter of the catalyst material established thereon.

6. The apparatus as defined in claim 1 wherein the crystalline surface is substantially vertical.

7. The apparatus as defined in claim 1, further comprising a substrate upon which the crystalline surface is established, wherein the crystalline surface is established at any non-zero angle with respect to a surface plane of the substrate.

8. The apparatus as defined in claim 1 wherein the crystalline surface is substantially horizontal.

9. The apparatus as defined in claim 1, further comprising a nanowire grown from the region.

10. A method of using the apparatus as defined in claim 1, the method comprising exposing the catalyst material to a precursor gas that initiates growth of the nanowire from the region.

11. A method for controlling a position of a catalyst material, the method comprising:
providing a crystalline surface; and
growing a feature on at least a portion of the crystalline surface such that the feature has a region with high surface curvature.

12. The method as defined in claim 11 wherein providing the crystalline surface includes forming the crystalline surface via lithography and etching.

13. The method as defined in claim 11, further comprising establishing a mask layer on the crystalline surface such that the at least a portion of the crystalline surface remains exposed.

14. The method as defined in claim 11 wherein growing is accomplished via epitaxy.

15. The method as defined in claim 11 wherein a portion of the feature remains substantially parallel to the crystalline surface during growth.

16. The method as defined in claim 11, further comprising continuing growth at least until the region has a zero-dimensional termination or a one-dimensional termination.

17. The method as defined in claim 16, further comprising establishing i) a catalyst nanoparticle on the zero-dimensional termination or ii) at least one catalyst nanoparticle on the one-dimensional termination.

18. The method as defined in claim 17, further comprising growing a nanowire from a portion of the feature directly adjacent the catalyst nanoparticle or the at least one catalyst nanoparticle.

19. The method as defined in claim 11 wherein growing the feature includes forming crystal planes inclined at a non-zero angle with respect to the crystalline surface, whereby the crystal planes bound the growing feature.

20. The method as defined in claim 11, further comprising:
establishing the catalyst material on exposed areas of the feature;
annealing the catalyst material, thereby causing the catalyst material to agglomerate at the region.

21. The method as defined in claim 20, further comprising growing a nanowire from the region.
